(19) United States
(12) Patent Application Publication
(10) Pub. No.: US 2006/0106472 A1
(43) Pub. Date: May 18, 2006

(54) Method and apparatus for normalizing sound recording loudness

(76) Inventors: Eric Douglas Romesburg, Chapel Hill, NC (US); William Chris Eaton, Cary, NC (US)

Correspondence Address: COATS & BENNETT/SONY ERICSSON, 1400 CRESCENT GREEN, SUITE 300, CARY, NC, 27511, US

(21) Appl. No.: 10/990,061

(22) Filed: Nov. 16, 2004

(51) Int. Cl. G06F 17/00; H03G 3/00

(52) U.S. Cl. 700/94; 381/104

(57) ABSTRACT

A method and apparatus normalizes the playback loudness of stored sound recordings to avoid objectionable variations in perceived loudness between different sound recordings at the same volume setting. In an exemplary processing method, a stored sound recording is processed to determine its loudness. That loudness, or some value derived from it, is then used to set the playback gain used for playing back the sound recording. Thus, for a given volume setting, the playback gain can be set lower for louder recordings, and higher for quieter recordings. In one or more exemplary embodiments, sound recordings are processed as received, or at least some time in advance of their first playback, so that a loudness-based gain compensation parameter can be calculated and stored for them. The corresponding stored gain control parameter can then be selected and used responsive to selecting a particular sound recording for playback.

### BACKGROUND OF THE INVENTION

The present invention generally relates to audio playback, and particularly relates to compensating the playback gain of individual sound recordings based on their loudness.

The loudness of a given sound recording influences its perceived playback loudness. Thus, for the same playback volume setting, one sound recording may be perceived by a listener as being louder or quieter than another one. These resulting differences in playback loudness can be particularly problematic in certain contexts.

For example, it is now common practice for cellular handset users to download custom ring tones to their handsets. With the proliferation of custom ring tones, handset users can change ring tones to suit their changing likes and dislikes, and can assign different ring tones to different callers. However, the characteristic loudness of different ring tone files can vary dramatically, and this results in objectionable variations in perceived ringer loudness between different ring tones for the same ringer volume setting.

Similar problems arising from variations in recording loudness arise in voice mail systems, and the like. In such systems, the perceived playback loudness varies between messages for the same playback volume setting because of differences in the characteristic loudness of the individual stored messages.

Of course, playback volume problems resulting from variations in the loudness of individual sound recordings is not limited to the above two contexts. Variations in sound recording loudness arise in a tremendous number of contexts. For example, as music is increasingly stored, sold, and transferred, in digital format, users that have amassed collections of digital music files with potentially significant differences in their characteristic loudness may face the same playback problems.

### SUMMARY OF THE INVENTION

The present invention comprises a method and apparatus to normalize the playback loudness of one or more stored sound recordings, which may be digital audio files, for example. Each such file is processed to determine a gain control parameter based on the recording's loudness. By way of non-limiting example, a given sound recording's loudness can be determined by making a RMS measurement of its amplitude values. The gain control parameter for a sound recording that had a high loudness measurement would reduce the effective playback gain for a given volume setting. Conversely, the gain control parameter for a sound recording that had a low loudness measurement would increase the effective playback gain for a given volume setting. In this manner, the perceived playback loudness of different sound recordings for a given playback volume setting can be normalized using corresponding stored gain control parameters.

Thus, in an exemplary embodiment, the present invention comprises a method of processing sound recordings for improved playback. The method comprises analyzing a stored sound recording to determine its loudness, determining a gain control parameter for the sound recording based on the loudness, and storing the gain control parameter for setting a playback gain during subsequent playback of the sound recording. The gain control parameters determined for multiple sound recordings can be stored individually, such as in separate data files or entries, or embedded into the sound recordings themselves, or stored collectively in a data structure having multiple entries. In any case, when a given sound recording is selected for playback, the corresponding gain control parameter also can be retrieved from memory for use in normalizing the playback loudness of the recording.

An exemplary apparatus supporting the above method, or variations of it, comprises one or more processing circuits con,figured to process a stored sound recording to determine its loudness, determine a gain control parameter for the sound recording based on the loudness, and store the gain control parameter for setting a playback gain during subsequent playback of the sound recording. Functionally, the one or more processing circuits can be arranged as a loudness determination circuit configured to determine the loudness of the sound recording, and a gain control parameter calculation circuit configured to determine the gain control parameter based on the loudness.

However, since the present invention may be embodied in hardware, software, or any combination thereof, significant flexibility exists regarding its implementation. For example, the present invention's playback loudness normalization method may be implemented in whole or in part as stored program instructions for execution by a general or special purpose microprocessor or other digital processing circuit.

Significant flexibility also exists regarding the applications in which the present invention may be used. In one exemplary embodiment, a portable communication device, such as a mobile station, pager, Portable Digital Assistant (PDA), or the like, is configured to normalize the playback loudness of stored ring tones. In other words, for a given ringer volume setting, operation of the present invention eliminates (or at least reduces) potentially objectionable variations in the perceived loudness of different ring tones. Such operation is particularly beneficial where a user's communication device is configured to use different ring tones for different Caller IDs, etc.

In another exemplary embodiment, a network-based voice mail server uses the present invention's method to normalize the playback loudness of stored voice mail messages. Thus, before playing back stored voice mail messages to a given network subscriber, the server can determine (and store) a gain control parameter for each message, and then use that parameter to set the playback gain of the message. With this approach, the potentially wide variation in the loudness of voice mail messages is compensated for through use of the gain control parameters, and subscribers thus enjoy a more uniform message loudness when playing back their stored voice mail messages. Note that loudness normalization can be done in the network, such as by scaling or offsetting the amplitude values comprising a stored message before (or during) transmission to the subscriber. Compensation also can be done at the subscriber's device based on receiving scaling information from the network, for example.

The present invention has broad applicability beyond the ring tone and voice mail loudness normalization. Its loudness normalization processing can, for example, be applied to digital music libraries comprising digital audio files potentially obtained from different sources and potentially subject to wide variations in recorded loudness. Thus, music player software on a Personal Computer (PC), or on a digital media server accessible via the Internet, may be configured to generate (and store) gain control parameters for individual audio files such that the playback loudness of each file is normalized. In the server application, normalization can be performed by the server and normalized file data can be streamed or transferred, or the server can stream or transfer raw file data, but additionally send the corresponding gain control parameter(s). In that latter scenario, the receiving playback device or system can use the received gain control parameter to normalize the raw file data.

Of course, the present invention is not limited to the above features and advantages. Those skilled in the art will recognize additional features and advantages of the present invention upon reading the following detailed description, and upon viewing the accompanying figures.

### BRIEF DESCRIPTION OF THE DRAWINGS

FIG. 1 is a diagram of an exemplary device or system 10 con figured to carry out playback loudness normalization in accordance with one or more embodiments of the present invention.

FIG. 2 is a diagram of exemplary gain control parameter determination that can be embodied in the apparatus of FIG. 1.

FIG. 3 is another diagram of device or system 10, further including a playback processor and audio playback circuit.

FIG. 4 is a diagram of exemplary playback loudness normalization that can be embodied in the apparatus of FIG. 3.

FIG. 5 is a diagram of additional, exemplary playback loudness normalization processing details.

FIG. 6 is another diagram of additional, exemplary playback loudness normalization processing details.

FIG. 7 is a diagram of an exemplary device configured according to one or more embodiments of the present invention.

FIG. 8 is a diagram of an exemplary mobile station—e.g., a cellular radiotelephone handset—that is configured according to one or more embodiments of the present invention.

FIG. 9 is a diagram of a wireless communication network, including a voice mail server that is configured according to one or more embodiments of the present invention.

### DETAILED DESCRIPTION OF THE INVENTION

Before turning to the accompanying figures, it may be helpful to frame the present invention in terms of its underlying gain compensation process. The present invention provides a method and apparatus whereby one or more stored sound recordings are processed to determine their loudness. A gain compensation parameter is determined for each such processed sound recording based on the recording's loudness, and that gain compensation parameter is stored. When a given sound recording is selected for playback, the corresponding gain compensation parameter is used to fix the playback gain used for playing the sound recording, which normalizes the recording's playback loudness. That is, the playback loudness of two different sound recordings having significantly different recording loudness is made substantially the same by compensating the playback gain used for each recording according to the recording's corresponding gain compensation parameter.

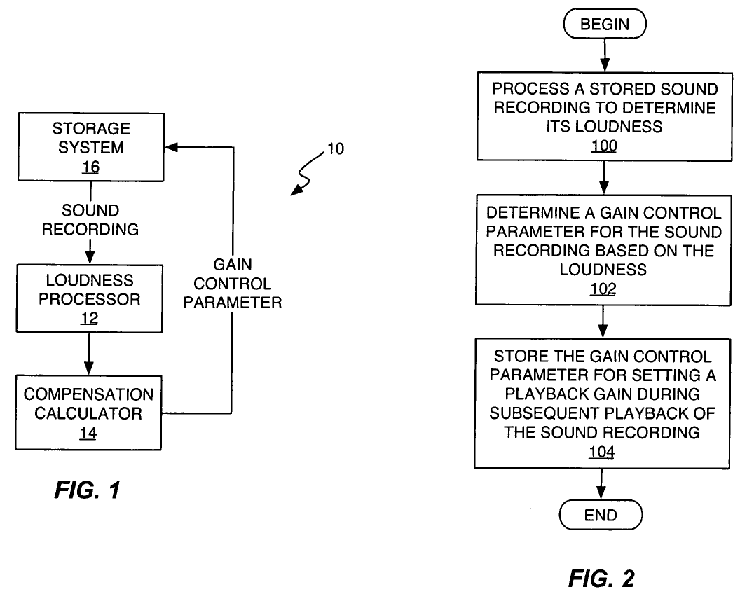

With the above method in mind, FIG. 1 functionally illustrates at least a portion of an audio processing device or system 10 comprising a loudness processor 12 and a compensation calculator 14. System 10 further comprises, or is associated with, a storage system 16 that is configured to store one or more sound recordings. In turn, loudness processor 12 is configured to obtain (directly or indirectly) a stored sound recording from storage system 16, and process that recording to determine its loudness. The measured loudness is then used by compensation calculator 14 to determine a corresponding gain compensation parameter that is stored for use in setting the playback gain during subsequent playback of the sound recording.

FIG. 2 illustrates exemplary processing logic that outlines this method of gain compensation. Such processing logic can be implemented in hardware, software, or any combination thereof. In one embodiment, the processing logic of system 10 is implemented as computer program instructions for execution by a microprocessor, or the like. Such instructions may be implemented as software, firmware, or microcode. In other embodiments, the processing logic is implemented in hardware, such as an Application Specific Integrated Circuit (ASIC), a Field Programmable Gate Array (FPGA), a Complex Programmable Logic Device (CPLD), or the like. Regardless, some type of processing circuit, whether hardware, software, or some combination thereof, may be used to implement the present invention.

Regardless of the particular implementation details, processing begins with processing a given stored sound recording to determine its loudness (Step 100). With a measure of the recording's loudness thus determined, processing continues with a determination of a corresponding gain control parameter (Step 102). The gain control parameter can be determined according to an inverse relationship with the recording's loudness—e.g., a 1/x relationship wherein the gain control parameter is smaller for a greater loudness value. Of course, the gain control parameter can be the loudness the value, or some direct multiple thereof, since the nature of the associated audio playback system's volume (gain) control arrangement largely determines the most suitable form for the gain control parameter.

However the gain compensation parameter is determined, and whether it is set as a scaling factor, or set as a dB offset value, exemplary processing continues with storage of the gain control parameter (Step 104). Such storage may comprise writing the gain control parameter to a file or other data structure contained in storage system 16, or may comprise appending, or otherwise, integrating the gain control parameter into the sound recording. This latter approach may be particularly attractive for digital audio files having extra data fields available in them and/or the ability to add to or change file header information.

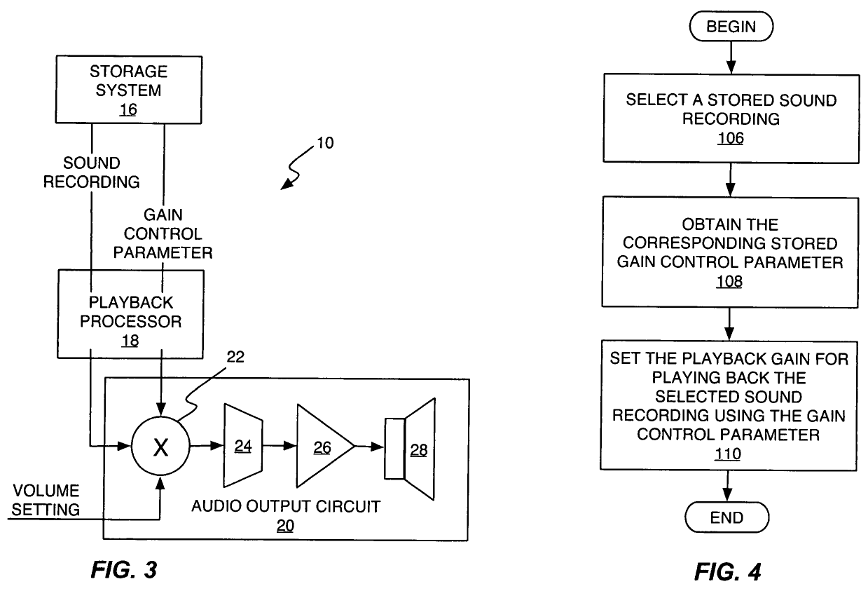

With the gain control thus determined and stored, FIG. 3 functionally illustrates a playback processor 18 and an associated audio output circuit 20, which comprises a gain control circuit 22, an analog-to-digital converter 24, an audio amplifier 26, and an audio output transducer (speaker) 28. Playback processor 18 directly or indirectly accesses a selected sound recording from storage system 16 for playback, and uses the recording's corresponding stored gain control parameter to set the playback gain via gain control circuit 22. Note, too, that the gain control circuit 22 also may respond to a playback volume control input, such that the overall gain is set as a function of the gain compensation parameter and the volume setting.

In the context of FIG. 3, the loudness-based gain control compensation occurs in the digital domain, which may be a convenient approach if the source sound recording is a digital audio file. Thus, the gain control circuit 22 effectively may adjust its nominal gain as determined by the volume control input up or down as a function gain control parameter's value. That adjustment may be based on adding or subtracting an offset value to the digital (amplitude) values of the sound recording, or by mathematically scaling those values up or down. If the gain control parameter is calculated with respect to the “full scale” value of the sound recording, the gain adjustment will be inherently appropriate for the (digital) amplitude range of the sound file. Note, too, that the gain setting fixed by the gain compensation parameter for playback of the sound recording can be set separately from the gain setting fixed by the currently selected volume setting. In this case, two gain control circuits may be placed in series, for example, with one controlled by the gain control parameter, and one controlled by the volume control input.

Those skilled in the art will appreciate that the sound recordings of interest may be stored in analog format, such as on tape, etc., in which case the corresponding gain compensation values can be determined in the analog or digital domains. Similarly, the playback gain setting step can be done in the digital or analog domains. By way of non-limiting example, a gain compensation parameter may be determined in the analog domain, converted to a digital value for convenient storage, and then applied during playback of the corresponding recording in either the digital domain, or in the analog domain after digital-to-analog conversion. In broad terms, the present invention thus contemplates all digital, all analog, and mixed analog/digital implementations of its exemplary loudness normalization method.

The exemplary processing logic illustrated in FIG. 4 may be used to implement the functionality embodied in the circuit of FIG. 3. In this context, processing begins with the selection of a stored recording (Step 106). The selection of a particular sound recording, which may be in a temporary buffer and/or in a permanent, non-volatile memory, can be triggered by user input or by some other selection mechanism—such as the ring tone selection and playback logic of a cellular handset or other type of wireless communication device.

After the particular sound recording is selected, or at least identified, the processing logic obtains the stored gain control parameter corresponding to the selected sound recording (Step 108). The gain control parameter can be stored in the same memory as the sound recording, or stored in a different memory. Also, the gain control parameter can be stored in a single file that is, for example, linked to the sound recording by file name, or by some other mechanism for logically associating stored gain control parameters with their corresponding stored sound recordings. Alternatively, a plurality of gain control parameters could be stored together in a common data structure—e.g., list or table entries—that can be indexed by sound recording identifiers. As a further alternative, the gain control parameters can be stored in the sound recordings themselves, although this latter approach is most advantageous for sound recordings having file types that allow appending or adding information—e.g., variable length header or data fields that can be populated with custom information.

However stored and retrieved, exemplary processing continues with setting the playback gain—e.g., increasing or decreasing a digital or analog gain in the playback signal chain—based on the gain control parameter (Step 110). By way of a simple example, one might imagine that the device in question has a current volume control setting of “5” on a volume scale that ranges from 1 to 10. Without benefit of the present invention, playing back a sound recording that has a high recording loudness at the current volume setting may result in an objectionably loud playback volume. Conversely, if the selected sound recording has a low recording loudness, then playback at the current volume setting might result in an objectionably low playback volume. By operation of the present invention, which adjusts the playback gain for individual sound recordings based on their individual recording loudness, the playback volumes of different sound recordings are normalized for a given current volume setting.

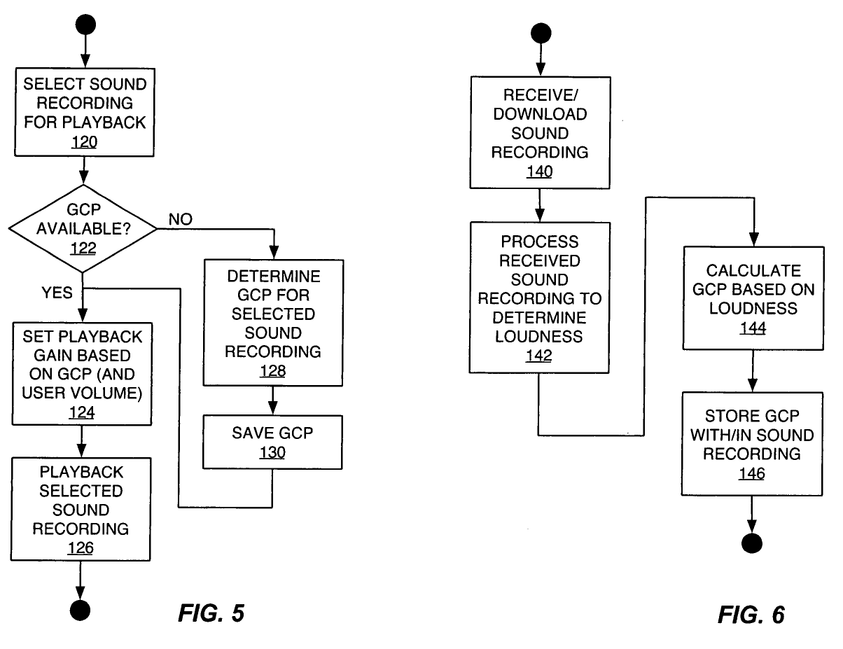

The generation of a gain control parameter (also referred to as a “GCP”), and usage of that parameter to fix the playback gain settings for a particular sound recording's playback can be made automatic. FIG. 5 illustrates exemplary processing, wherein gain control parameters are retrieved from storage or generated “on-the-fly” as needed. Note that on-the-fly generation may be carried out in real-time at the nominal playback rate of the sound recording, or at an accelerated rate. Accelerated processing at potentially many times the playback rate means that a gain control parameter can be determined in several milliseconds, for example, and is the preferred approach assuming sufficient computing power is available. If any noticeable delay before beginning playback is incurred for GCP generation, the device in question may be configured to provide some type of indication to its user—i.e., an audible and/or visual delay notice.

Thus, exemplary processing begins with selection of a sound recording for playback (Step 120). Again, such selection may be based on direct or indirect user input, or based on some other process, such as a ring event process, a song play list process, etc. The processing logic determines if a gain control parameter is available for the selected sound recording (Step 122). If so, processing continues with setting the playback gain based on the gain control parameter's value and the current volume setting (Step 124). That may be done by setting a first gain as a function of the gain control parameter and setting a second gain as a function of the volume setting, or by setting a composite gain as a function of the combination of the gain control parameter's value and the current volume setting.

Processing continues with the sound recording being played back—e.g., output as an audible signal and/or as a source signal for another device or system—at the compensated playback gain setting (Step 126). Note that if, at Step 122, no gain control parameter was available for the selected sound recording, the exemplary processing logic calls processes the sound recording to determine the appropriate gain control parameter (Step 128), which it saves (Step 130), and uses for playback gain compensation as outlined above for Steps 124 and 126.

In looking at further methods of automatic determination of gain compensation parameters for stored sound recordings, FIG. 6 illustrates processing logic wherein the determination of gain compensation parameters is made responsive to receiving a sound recording into temporary (or permanent) memory. Thus, processing begins with the device receiving/downloading a sound recording (Step 140), which may comprise a cellular handset, pager, music player, etc., receiving a digital audio file via wireless or wired transfer from a supporting communication network, or from a host device (PC) via a local interface port.

Upon receipt of the sound recording, processing continues with analyzing the sound recording to determine its loudness (Step 142). Processing then turns to determining the appropriate gain control compensation parameter value based on the determined loudness of the sound recording (Step 144). That gain control parameter is then stored for use in fixing the playback gain to be used during subsequent playback of the sound recording (Step 146). Note that if the processing capability of the device is sufficiently great, the automated determination of the gain control parameter responsive to receiving a new sound recording can be done transparently to the device user—i.e., with no perceptible interruption in normal device processing, and with no perceptible delay in the playback availability of the newly received sound recording. Of course, if there are any potentially noticeable delays, the device can be configured to provide some notification to the user.

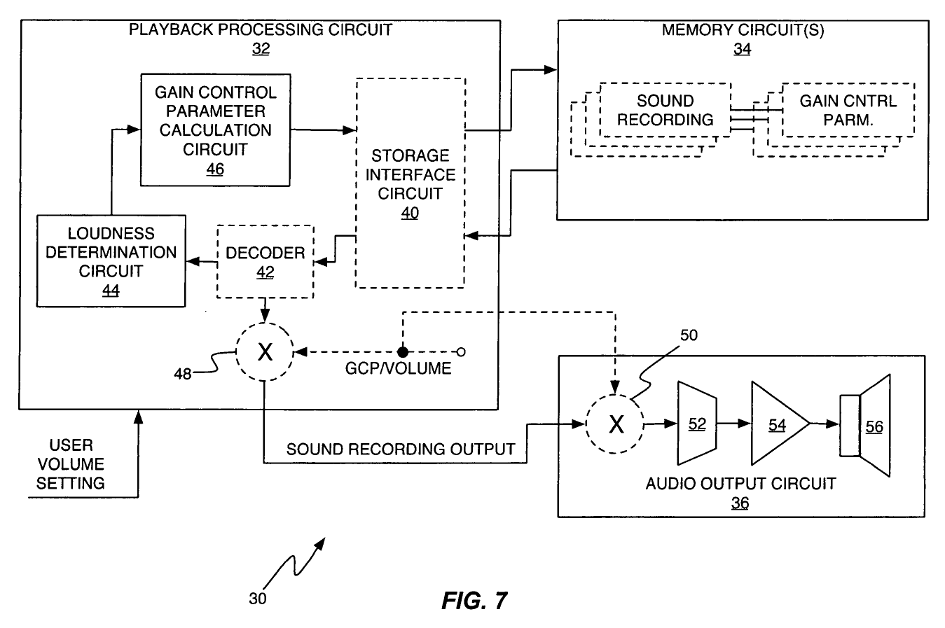

With respect to devices in which the present invention can be embodied, FIG. 7 illustrates an exemplary device (or system) 30 that comprises a playback processing circuit 32, one or more memory circuits 34, and, optionally, an audio output circuit 36. Memory circuit(s) 34 may comprise different memory devices, and may comprise different types of memory—e.g., Random Access Memory (RAM) for scratchpad use and temporary data buffering, Read Only Memory (ROM) for storing program data, including program instructions to implement the present invention's loudness normalization processing, and Non-Volatile RAM (NVRAM), Electrically Erasable Programmable ROM (EEPROM), FLASH memory, etc.

Regardless of the particular kind(s) of memory used, the playback processing circuit 32 may include a storage interface circuit 40 for reading and writing to one or more types of memory devices, or for interfacing to other processing circuits having access to such devices. Playback processing circuit 32 may further include a playback decoder 42 that is operative to decode and/or decompress stored sound recordings. By way of non-limiting example, any included decoder 42 can be configured to handle one or more proprietary and/or standardized sound recording formats. Thus, decoder 42 can be configured to process MPEG Layer 3 (MP3) digital audio files, WINDOWS Media Audio (WMA) digital audio files, Adaptive Transform Acoustic Coding (ATRAC) digital audio files, Advanced Audio Coding (AAC) digital audio files, and others. Device 30 thus can be configured as needed or desired to perform its exemplary loudness normalization for any one or more of a variety of digital audio file types.

Loudness normalization according to the present invention represents a superior solution, for example, as compared to changing the gain of an originally encoded audio file. Specifically, changing the originally encoded gain of an audio file requires decoding and re-encoding. Since most audio compression schemes are lossy, the decoding and re-encoding process introduces additional quantization noise and saturation distortions. In contrast, the present invention's playback normalization does not require audio file re-encoding, and permits application of playback loudness normalization simultaneous with user gain control (volume control).

Thus, in one or more embodiments, playback circuit 32 includes a loudness determination circuit 44 that is configured to determine the loudness of stored sound recordings via hardware, software, or some combination thereof. In this context, the term “loudness” should be given broad construction. Thus, loudness determination circuit can be configured to determine the loudness of stored sound recordings based on making Root-Mean-Square (RMS) measurements of them. In digital audio files, the digitized amplitude values can be processed to generate a RMS measurement for a given file. Similarly, the loudness determination circuit 44 can be configured to determine loudness based on making Root-Sum-Square (RSS) measurements. Again, for digital audio files, RSS measurements can be based on the digitized amplitude values in the file. Of course, RSS and/or RMS measurements can be made in the analog domain as needed or desired, for either analog or digital sound recordings. In one or more other embodiments, the loudness of stored sound recordings is determined by identifying peak levels and/or average levels in the recording. For each recording, these measurements preferably are referenced to the “full-scale” value used for the recording.

Additionally, any of the above loudness measurement methods can be adjusted in accordance with how the human ear perceives sound. Even at the same playback volume, the human ear perceives sounds within certain frequency ranges as being louder than sounds in other frequency ranges. More particularly, lower and higher frequency sounds have a lower perceived loudness than mid-range frequencies. Thus, the loudness determination circuit 44 can be configured to generate a frequency-weighted loudness measurement for the stored sound recordings, such that the corresponding gain control parameters reflect psycho-acoustic considerations.

In this way, the gain compensation parameter used to normalize the playback loudness of a given stored sound recording reflects the psycho-acoustic characteristics of that sound recording. Gain control parameters for given sound recordings may be calculated to have less or more gain attenuation than they otherwise would if determined irrespective of the recordings' frequency characteristics. Simply put, a frequency-independent gain control parameter calculation generally will yield a different value than a frequency-dependent calculation. The additional complexity of calculating the gain control parameters based on a psycho-acoustic model—i.e., frequency-dependent loudness determination—may be particularly beneficial for ring tones, which may comprise short playback times and relatively narrow frequency ranges.

Having obtained some measure of the sound recording's loudness, gain control parameter calculation circuit 46 determines a corresponding gain compensation parameter to be used in fixing the playback gain for the recording. In some embodiments, the gain compensation parameter simply is the loudness value determined for the sound recording. That value may, as noted several times herein, be a RMS value, RSS value, peak value, peak-to-average value, average value, or other loudness measurement, and any or all such measurements may or may not be frequency-weighted. Note, too, that in at least one embodiment, the gain compensation parameter actually may comprise more than one value.

In another embodiment, the gain compensation parameter is a calculated value derived from the loudness measurement. Thus, it may be a simple 1/x relationship, or it may be based on a more complex derivation. According to one method, the gain compensation parameter is a gain adjustment value determined from the loudness measurement, which adjustment value may be a scaling factor that multiplicatively compensates the playback gain, or may be an offset factor that compensates playback gain via addition or subtraction. Regardless, the range and resolution of the gain compensation parameter depends on the implementation details of the audio playback system. In any case, the gain compensation parameter is stored in memory for playback gain compensation.

In carrying out that playback gain compensation, the playback processing circuit 32 may comprise a gain control circuit 48 that applies the gain compensation parameter to the (decoded) sound recording output. Playback processing circuit 32 also may receive a playback volume control input, and thus may set the gain of the sound recording output signal based on a combination of the gain control parameter and the current volume control input value. For example, if the gain compensation parameter is applied as a scaling factor x, and the volume control setting is applied as a scaling factor y, then the combined gain setting may be expressed as x·y. Of course, in an offset-based compensation, the volume control gain y can be adjusted by the gain compensation parameter x as y±x.

If the gain control circuit 48 is omitted from the playback processing circuit 32, it may output a gain control signal as well as the sound recording output signal. Those two signals may be provided to the audio output circuit 36, which may be co-located with the playback processing circuit, or remote from it. In either case, the gain control signal output by playback processing circuit can be a combination of the volume and compensation gains, or can be just the compensation gain, with the volume control input directly to the audio output circuit 36.

If the audio output circuit 36 receives the uncompensated sound recording output signal as its input, then it can include a gain control circuit 50 that is configured to apply the gain compensation parameter and, optionally, the volume gain setting to the input signal. If the audio output circuit receives a gain-compensated sound recording output signal from the playback processing circuit 32, then such gain control can be omitted. Those skilled in the art will appreciate that such implementation details are not limiting aspects of the present invention, and thus it should be understood that such details may be varied as needed or desired.

In any case, the exemplary audio output circuit 36 further includes a digital-to-analog converter 52 that converts the gain-compensated sound recording signal into an analog waveform, which may be a stereo or multi-channel waveform, for input to amplifier 54. In turn, amplifier 54 outputs a signal suitable for driving an audio output transducer 56, such as a low-impedance speaker. Note, too, that processing in the digital domain may be a matter of convenience in, for example, a portable music player that is configured to play digital music files, but such processing is not a limiting aspect of the preset invention. Indeed, the gain compensation processing, and the sound recording itself, may be in (or converted to) the analog domain.

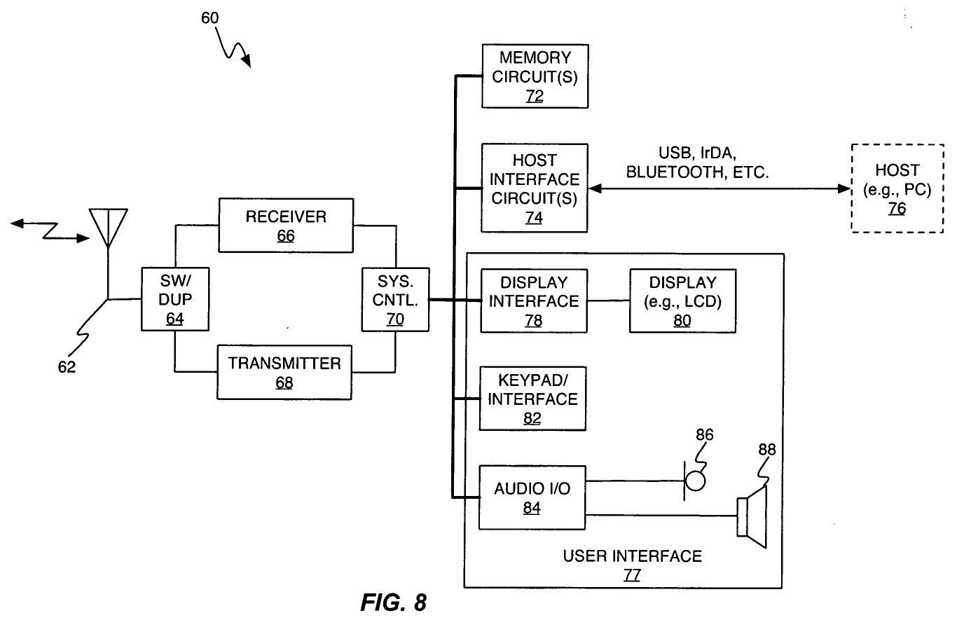

Further, while it should be understood that the playback loudness normalization method of the present invention can be advantageously applied in essentially any kind of device or system that plays back stored sound recordings, or manages the playback of such recordings, the present invention may have particular advantages in certain contexts. For example, FIG. 8 illustrates an exemplary wireless communication device 60, which may be a cellular radiotelephone, wireless pager, Portable Digital Assistant (PDA) with communication capabilities, or the like. Thus, its implementation details may vary as a function of its intended purpose (or purposes), but the exemplary device 60 is configured to carry out the present invention's method of playback loudness normalization for at least some of the sound recordings stored by device 60.

While not every functional element illustrated relates to supporting the particular signal processing comprising the present invention, the exemplary device 60 comprises a transmit/receive antenna assembly 62, a switch/duplexer 64, a radiofrequency (RF) transceiver comprising a receiver 66 and a transmitter 68, a system controller 70, one or more memory circuits 72, a host interface 74 to communicate with a host system 76 (e.g., a PC), and an user interface 77. An exemplary user interface 77 comprises a display interface 78 and a display 80, which may be a graphics-capable color LCD or other screen type, a keypad interface and keypad 82, and an audio input/output subsystem 84. The audio subsystem 84 may be connected to an audio input transducer 86 (e.g., a microphone) and to an audio output transducer 88 (e.g., a speaker).

The present invention, which may comprise hardware, software, or both, may be implemented in system controller 70. An exemplary system controller 70 comprises one or more microprocessors and/or other processing circuits, and supporting circuits, as needed. Thus, system controller 70 may be configured to read a sound recording from memory circuit(s) 72 over a data bus, for example, process the sound recording to determine its loudness and a corresponding gain control parameter, and then write the gain control parameter to memory circuit(s) 72 for later use in normalizing the playback loudness of the sound recording responsive to it being selected for playback. Of course, the gain control parameter can be determined for selected sound recording on the fly, and held in working memory for immediate loudness normalization of the selected sound recording.

In terms of obtaining sound recordings, device 60 may “download” sound recordings via wireless signaling with a supporting wireless communication network using receiver 66 and transmitter 68, and/or it may download sound recordings from a local host 76 via host interface circuit(s) 74. Host interface circuit(s) 74 may include essentially any type of local communication interface circuit. By way of non-limiting examples, the host interface circuit(s) 74 may comprise one or more of the following: a Universal Serial Bus (USB) interface, an IEEE 1394 (Firewire) interface, an infrared (e.g., IrDA) interface, and a short-range radio interface (e.g., Bluetooth, 802.11, etc.).

Note, too, that the audio subsystem 84 may comprise a microprocessor or other (possibly dedicated) processing circuit that can be configured to carry out exemplary playback loudness normalization in accordance with the present invention. Indeed, the present invention can be implemented using relatively modest processing resources, and is practically implemented using inexpensive programmable or custom logic circuits. Thus, the present invention may be commercially embodied in the form of pre-programmed or pre-configured integrated circuit devices, as software for execution on specified microprocessor/microcontroller cores, and/or as digital synthesis files for use with Electronic Design Automation (EDA) tools of the type used to design integrated circuits.

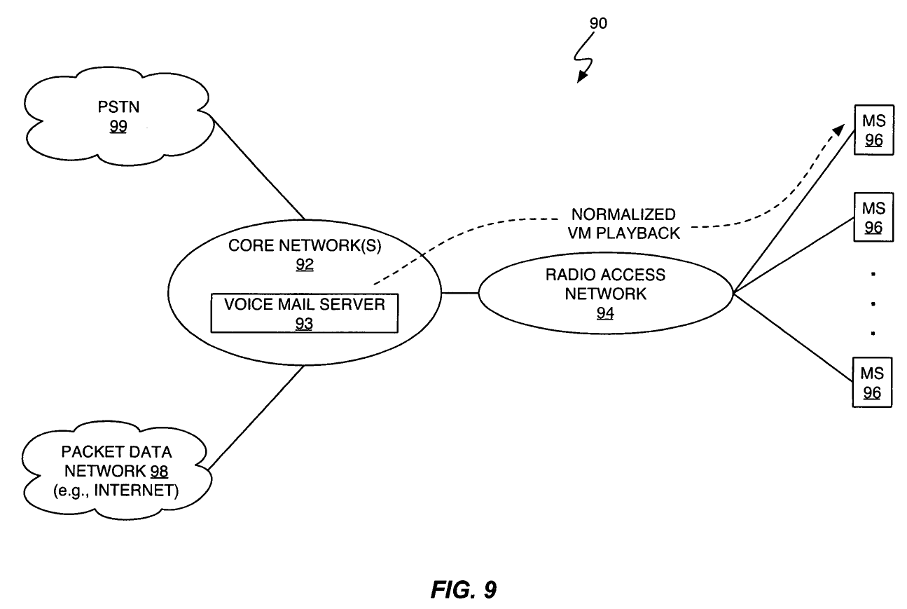

FIG. 9 further evidences the present invention's flexibility, not only in terms of its implementation details, but also in terms of its applications. A wireless communication network 90 comprises one or more Core Networks (CNs) 92, which, for example, may be packet and/or circuit switched core networks in the manner of IS-95B, IS-2000, or Wideband CDMA (WCDMA) wireless communication networks. Of particular interest, CN(s) 92 include a voice mail server system 93 that stores voice mail messages targeted to users of the network 90.

Those stored messages can be delivered through a Radio Access Network (RAN) 94 to individual mobile stations 96, which, for example, may be configured as shown for device 60 in FIG. 8. The messages typically come in from a variety of sources, such as from various kinds of user equipment communicatively coupled to Public Data Networks 98 (e.g. Internet), from users of the Public Switched Telephone Network (PSTN) 99, and from other users of network 90. Coming as they do from these disparate sources, the voice mail messages stored by the voice mail server 93 typically have varying loudness levels. Thus, playback of multiple messages at a user's mobile station 96 may suffer from objectionable variations in loudness from message to message.

If individual messages are transferred to the mobile station 96 and held in a temporary buffer for playback, then the mobile station 96 can perform playback loudness normalization for each one in advance of playing the message. However, if the messages are streamed to the mobile station for real-time playback, the voice mail server 93 can perform playback loudness normalization as part of its message streaming operations. That processing can be based on voice mail serving 93 receiving incoming voice mail messages, processing them to determine loudness compensation parameters, and storing those parameters for playback loudness normalization.

The loudness normalization can be based on applying gain compensation to the data comprising a given message as it is being streamed to the user's mobile station 96. Alternatively, it can be based on transmitting the gain compensation parameter to the mobile station 96 at or before the start of message transmission, such that the mobile station 96 uses the received gain compensation parameter to perform playback loudness normalization for the message.

Those skilled in the art will immediately appreciate many other applications beyond voice mail loudness normalization, as described immediately above, and beyond the ring tone normalization described earlier herein. For example, the voice mail server 93 can be broadly viewed as any media server (e.g., a streaming media server) accessible through network 90, or more generally through the Internet. Thus, the present invention broadly applies to the playback loudness normalization of any type, or types, of stored sound recordings and finds direct application in portable communication devices—cell phones, pagers, PDAs—and in PCs, network servers holding media files for streaming or transfer, and the like. As such, the present invention is not limited by the foregoing discussion, nor is it limited by the accompanying figures. Rather, the present invention is limited only by the following claims and their reasonable, legal equivalents.

What is claimed is:

1. A method of processing sound recordings for improved playback comprising:
processing a stored sound recording to determine its loudness;
determining a gain control parameter for the sound recording based on the loudness; and
storing the gain control parameter for setting a playback gain during subsequent playback of the sound recording.

2. The method of claim 1, wherein storing the gain control parameter comprises storing the gain control parameter as an entry in a stored data structure configured to hold a plurality of such entries corresponding to a plurality of sound recordings.

3. The method of claim 1, wherein storing the gain control parameter comprises storing the gain control parameter as part of the sound recording.

4. The method of claim 1, wherein processing the stored sound recording to determine its loudness comprises, at a node in a communication network, processing a stored voice mail message, such that the gain control parameter enables gain compensation during subsequent playback of the voice mail message to a user of the communication network.

5. The method of claim 1, wherein processing the stored sound recording to determine its loudness comprises, at a wireless communication handset, processing a stored ring tone file, such that the gain control parameter enables gain compensation during subsequent playback of the ring tone file.

6. The method of claim 1, wherein the sound recording comprises a digital audio file, and wherein processing the stored sound recording to determine its loudness comprises analyzing the digital values comprising the digital audio file.

7. The method of claim 6, wherein analyzing the digital values comprising the digital audio file comprises calculating a frequency-weighted loudness parameter based on the digital values.

8. The method of claim 6, wherein analyzing the digital values comprising the digital audio file comprises calculating a psycho-acoustic modeling parameter based on the digital values.

9. The method of claim 6, wherein analyzing the digital values comprising the digital audio file comprises at least one of determining a Root-Mean-Square value for the digital values, determining a Root-Sum-Square value for the digital values, and determining a peak value for the digital values.

10. The method of claim 1, wherein processing the stored sound recording to determine its loudness comprises at least one of determining a Root-Mean-Square value for the sound recording, determining a Root-Sum-Square value for the sound recording, and determining a peak value for the sound recording.

11. The method of claim 1, further comprising setting the playback gain during playback of the sound recording based at least in part on the gain control parameter.

12. The method of claim 1, wherein setting the playback gain during playback of the sound recording based at least in part on the gain control parameter comprises generating an overall playback gain value based on a combination of the gain control parameter and a playback volume setting.

13. The method of claim 1, further comprising, in response to receiving audio data into a local memory as the sound recording, automatically performing the steps of processing the stored sound recording, determining the gain compensation parameter, and storing the gain compensation parameter.

14. The method of claim 1, further comprising in response to recognizing a first attempted playback of the sound recording, automatically performing the steps of processing the stored sound recording, determining the gain compensation parameter, and storing the gain compensation parameter.

15. An apparatus for improved playback of sound recordings comprising one or more processing circuits configured to:
process a stored sound recording to determine its loudness;
determine a gain control parameter for the sound recording based on the loudness; and
store the gain control parameter for setting a playback gain during subsequent playback of the sound recording.

16. The apparatus of claim 15, wherein the one or more processing circuits are further configured to provide playback processing of the sound recording, including playback gain control based on the stored gain control parameter.

17. The apparatus of claim 15, wherein the apparatus includes a digital audio playback circuit comprising the one or more processing circuits, and wherein the digital audio playback circuit is configured to store digital audio files as sound recordings in a local memory associated with the digital audio playback circuit, and play back the digital audio files according to gain control parameters individually determined and stored by the apparatus for respective ones of the digital audio files.

18. The apparatus of claim 17, wherein the apparatus comprises a wireless communication device that includes the digital audio playback circuit configured to control the playback gain of ring tone files stored by the device according to gain control parameters determined for the stored ring tone files.

19. The apparatus of claim 17, wherein the apparatus comprises a digital music player that includes the digital audio playback circuit.

20. The apparatus of claim 15, wherein the apparatus comprises a processing node in a wireless communication network configured to control the playback gain of stored voice mail recordings.

21. The apparatus of claim 15, wherein the one or more processing circuits comprise:
a loudness determination circuit configured to determine the loudness of the sound recording; and
a gain control parameter calculation circuit configured to determine the gain control parameter based on the loudness.

22. The apparatus of claim 21, wherein the one or more processing circuits further comprise a interface circuit configured to interface with one or more associated memory circuits for writing the gain control parameter to memory, and for reading the gain control parameter from memory.

23. The apparatus of claim 21, further comprising a gain control circuit configured to set the playback gain for the sound recording based at least in part on the gain control parameter.

24. The apparatus of claim 21, further comprising a playback processing circuit configured to control playback of the sound recording, and to set the playback gain for said playback based at least in part on the gain control parameter.

25. The apparatus of claim 21, wherein the loudness determination circuit comprises one of a Root-Mean-Square calculation circuit configured to calculate a Root-Mean-Square value for the sound recording, a Root-Sum-Square calculation circuit configured to calculate a Root-Sum-Square value for the sound recording, a peak value detection circuit configured to detect a peak value for the sound recording, and a recording level detection circuit configured to detect a recording level for the sound recording.

26. The apparatus of claim 15, wherein the one or more processing circuits are configured to determine the loudness of the sound recording as a frequency-weighted loudness parameter.

27. The apparatus of claim 15, wherein the one or more processing circuits are configured to calculate the loudness of the sound recording as a psycho-acoustic modeling parameter.

28. The apparatus of claim 15, wherein the one or more processing circuits are configured to calculate the loudness of the sound recording by determining at least one of a Root-Mean-Square value for the sound recording, determining a Root-Sum-Square value for the sound recording, and determining a peak value for the sound recording.

29. A method of normalizing the playback loudness of a stored sound recording comprising:
processing the sound recording prior to its playback to determine a loudness value for the sound recording; and
normalizing a playback loudness of the sound recording by setting a playback gain used for playing back the sound recording based on a gain compensation parameter determined from the loudness value of the sound recording.

30. The method of claim 29, further comprising storing the gain compensation parameter in memory, and retrieving the gain compensation from memory responsive to the sound recording being selected for playback.

31. A device operative to normalize the playback loudness of digital audio files, said device comprising:
a memory circuit configured to store a digital audio file; and
a playback processing circuit configured to determine and store a gain control parameter for the digital audio file based on analyzing a loudness of the digital audio file, and configured to normalize the playback loudness of the digital audio file by using the gain control parameter to set a playback gain for playing the digital audio file.

32. The device of claim 31, wherein the device comprises a wireless communication device that is configured to determine and store a gain control parameter for each one of one or more stored ring tone files, and wherein the playback processing circuit normalizes the playback loudness of a currently selected ring tone file for a given ringer volume setting based on the corresponding gain control parameter.

33. The device of claim 32, wherein the wireless communication device is configured to determine and store a gain control parameter for a given ring tone file responsive to receiving the ring tone file in a download operation.

34. A voice mail system operative to normalize the playback loudness of stored voice mail messages, said system comprising:
a memory circuit configured to store a voice mail message; and
a playback processing circuit configured to determine and store a gain control parameter for the voice mail message based on analyzing a loudness of the voice mail message, and configured to normalize the playback loudness of the voice mail message by using the gain control parameter to set a playback gain for playing the voice mail message.

35. The voice mail system of claim 34, wherein the voice mail system comprises a processing node in a communication network, the processing node comprising one or more memory circuits configured to store voice mail messages for users of the communication network, and comprising one or more digital logic circuits configured as the playback processing circuit.
